(19) United States
(12) Patent Application Publication
(10) Pub. No.: US 2005/0200026 A1
(43) Pub. Date: Sep. 15, 2005

(54) Contact structure for nanometer characteristic dimensions

(75) Inventor: Jhon Jhy Liaw, Hsin-Chu (TW)

Correspondence Address: TUNG & ASSOCIATES;Suite 120, 838 W. Long Lake Road, Bloomfield Hills, MI, 48302, US

(73) Assignee: Taiwan Semiconductor Manufacturing Co. Ltd.

(21) Appl. No.: 10/797,945

(22) Filed: Mar. 10, 2004

(51) Int. Cl. H01L 23/48

(52) U.S. Cl. 257/774

(57) ABSTRACT

A contact interconnect structure including the method of providing a semiconductor substrate including CMOS devices including active contact regions; forming a first set of dielectric layers to form a first thickness for etching a first set of openings through a thickness thereof including a bottom portion having a maximum width of less than about 70 nanometers; etching the first set of openings to contact active contact regions; filling the first set of openings with a first metal; forming a second set of dielectric layers to form a second thickness for etching a second set of openings through the second thickness comprising a bottom portion having a maximum width of less than about 70 nanometers; etching the second set of openings to provide electrical communication with the first set of openings; and, filling the second set of openings with a second metal to form contact interconnects.

### FIELD OF THE INVENTION

This invention generally relates to formation of nanometer scaled CMOS integrated circuits and more particularly to contact interconnect structures and method for forming the same to achieve reliable electrical contacts including to active contact regions in CMOS integrated circuits.

### BACKGROUND OF THE INVENTION

Increasingly, integrated circuits require a higher density of device integration with increasingly shrinking characteristic dimensions, such dimensions referred to as deep sub-micron or nanometer technology where characteristic (critical) dimensions such as gate length are expected to soon decrease below 60 nm as well as below 45 nm. The decreasing characteristic dimensions of integrated circuits creates a host of new processing problems as well as design problems which must be overcome to successfully achieve higher levels of integration.

Contact interconnects, also referred to as vias, are particularly critical for making contact with active areas of a transistor device including active contact regions such as the gate electrode and source and drain (S/D) regions. For example, as characteristic dimensions of transistor devices are scaled down to deep submicron dimensions, the contact opening width allowable is increasing limited due to the shrinking size of the contact areas. Conventional processing steps such as photolithography and reactive ion etching have increasingly limited process windows in order to make reliable contacts while the shortcomings of inadequate etching bias, etching profiles, premature etch stop, unintentional overetching of contact regions, and etch opening misalignment.

For example, in prior art processes, a metal filled contact interconnect or via have been used to make contact from the active contact regions including gate electrode and S/D regions to the first metallization layer through a single Interlayer-dielectric (ILD) layer, also referred to as a pre-metal dielectric (PMD) layer. In prior art approaches, The ILD layer is formed overlying the active devices followed by formation of metal filled contacts extending through the ILD layer thickness to electrically connect the active regions to an overlying metallization layer which begins the formation of wiring circuitry formed in multiple overlying metallization levels.

Due to signal delay concerns and IC design rules, the size of active contact regions in a scaling down process shrinks significantly faster than the thickness of the ILD layer, due to a desire to prevent stray capacitance from the metallization layer to the gate structure. As a result, contact interconnects must be formed with increasingly high aspect ratios which creates processing difficulties such as inadequate etching biases and profiles, premature etch stop, inadequate metal filling coverage, unintentional overetching into the contact regions, as well as inadequate lithography resolution due to the required thickness of resist layers when used as etching masks in high aspect ratio plasma etching process.

These and other shortcomings demonstrate a need in the semiconductor device integrated circuit manufacturing art for improved contact interconnects structures and a method for forming the same to form more reliable contact interconnects having smaller width dimensions while avoiding the various shortcomings of the prior art.

It is therefore an object of the present invention to provide improved contact interconnects structures and a method for forming the same to form more reliable contact interconnects having smaller width dimensions while avoiding the various shortcomings of the prior art.

### SUMMARY OF THE INVENTION

To achieve the foregoing and other objects, and in accordance with the purposes of the present invention, as embodied and broadly described herein, the present invention provides a contact interconnect structure and method for forming the same to achieve improved patterning, etching and metal filling characteristics.

In a first embodiment, the method includes providing a semiconductor substrate including CMOS devices including active contact regions; forming a first set of dielectric layers to form a first thickness for etching a first set of openings through a thickness thereof including a bottom portion having a maximum width of less than about 70 nanometers; etching the first set of openings to contact active contact regions; filling the first set of openings with a first metal; forming a second set of dielectric layers to form a second thickness for etching a second set of openings through the second thickness comprising a bottom portion having a maximum width of less than about 70 nanometers; etching the second set of openings to provide electrical communication with the first set of openings; and, filling the second set of openings with a second metal to form contact interconnects.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A-1E are cross sectional schematic representations of exemplary portions of an integrated circuit semiconductor device at stages of manufacture according to an embodiment of the present invention.

FIG. 2 is an exemplary process flow diagram including several embodiments of the present invention.

### DETAILED DESCRIPTION OF THE PREFERRED EMBODIMENTS

Although the method of the present invention is explained with reference to an exemplary CMOS transistor and shallow trench isolation (STI) structures, it will be appreciated that the shallow contact interconnects and method of forming the same may be applied in general to forming contact interconnects where an integrated circuit device or process may be improved by forming contact interconnects in a multi-step process to overcome processing issues and device performance issues related to forming high aspect ratio damascene openings. In addition, it will be appreciated that while the device and method of the present invention is particularly advantageously used for forming integrated circuit devices with characteristic dimensions (e.g., gate lengths) less than about 60 nm, including less than about 45 nm, that the method and structure may be used in forming larger characteristic dimension devices.

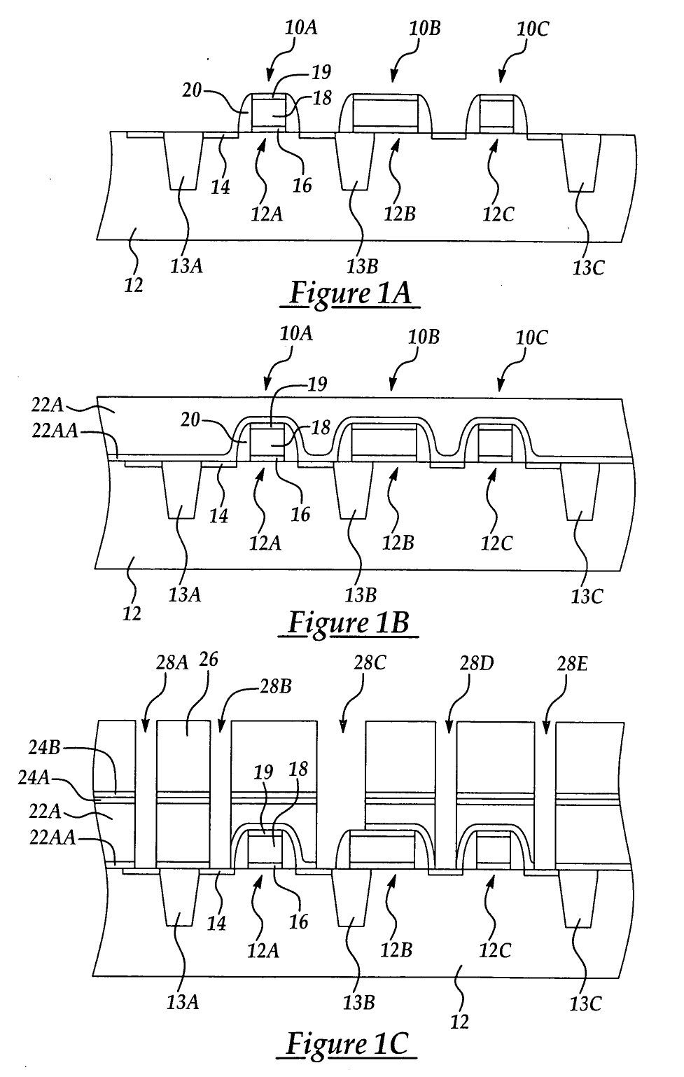

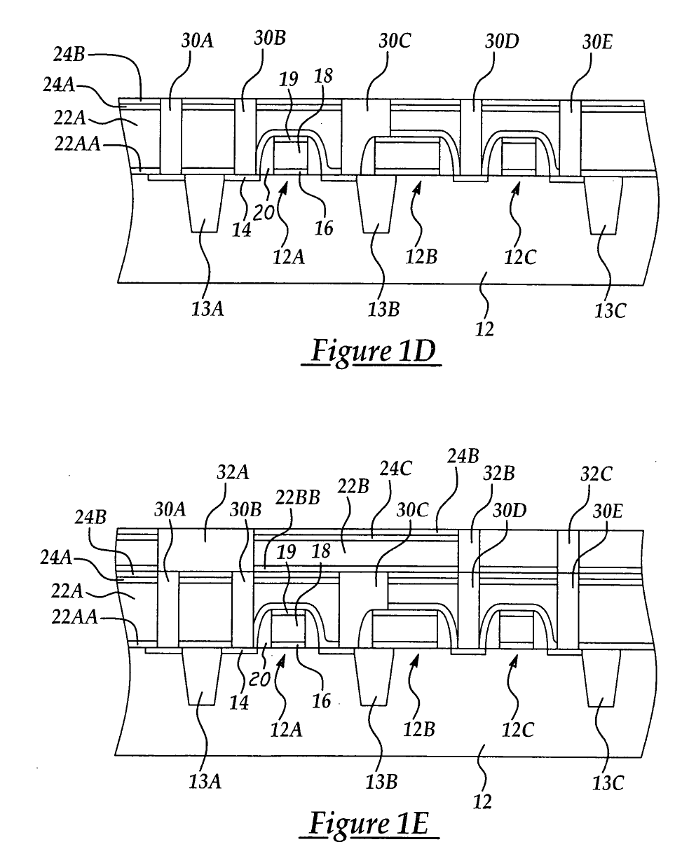

Referring to FIGS. 1A-1E in an exemplary embodiment of the method of the present invention, are shown cross-sectional schematic views of a portion of a semiconductor wafer during stages in production of a CMOS integrated circuit, for example FET transistor devices 10A, 10B, and 10C, forming a portion of logic or memory IC circuits. For example, referring to FIG. 1A is shown a semiconductor substrate 12 including an active regions including channel regions 12A, 12B, and 12C where the active regions are electrically isolated by isolation regions, preferably shallow trench isolation (STI) structures, e.g., 13A, 13B, and 13C which are formed by conventional methods including backfilling an STI trench formed in the semiconductor substrate with an oxide dielectric, for example TEOS oxide. It will appreciated that other methods for achieving electrical isolation may be used including LOCOS, field oxide, and silicon on insulator (SOI).

CMOS devices (e.g., FET transistors) 10A, 10B, 10C may form a portion of a logic or memory circuit and may be formed by conventional methods with conventional materials including first conductive active contact regions e.g., 14, for example formed over source/drain regions. The CMOS devices include respective gate structures which include conventional gate dielectric portions e.g., 16 and respective overly gate electrode portions e.g., 18C. In addition, the respective gates structures include pairs of offset spacers e.g., 20 on either side of the gate structures formed of silicon oxide, silicon nitride, silicon oxynitride or combinations thereof. The semiconductor substrate 12 may be formed of silicon, silicon on insulator (SOI), strained silicon, and silicon-germanium (SiGe), or combinations thereof.

Still referring to FIG. 1A, the gate structures including gate dielectric portions may be formed by conventional CVD deposition, lithographic patterning, and plasma and/or wet etching methods known in the art. The gate dielectric may be formed by any process known in the art, e.g., thermal oxidation, nitridation, sputter deposition, or chemical vapor deposition. Silicon oxide, silicon nitride, silicon oxynitride, high-K (e.g., K>8) dielectrics including transition metal oxide and rare earth oxides may be used for the gate dielectrics.

The gate electrode portion e.g., 18A, 18B, 18C of the gate structure may be formed of polysilicon, polysilicon-germanium, metals, metal silicides, metal nitrides, or conductive metal oxides. Second conductive active contact regions e.g., 19 are optionally formed in the uppermost portion of the gate electrodes along with first conductive contact regions e.g., 14 by conventional CVD or sputtering methods including silicidation to form self-aligned silicides a/s is known in the art. Preferably, the first and second active contact regions include one or a combination of conductive materials such as metals, such as Ti, Co, Ni, Pt, W and silicides thereof, e.g., TiSi₂, CoSi₂, NiSi, PtSi, WSi₂, as well as metal nitrides such as TiN and TaN, or combinations of the foregoing.

For example, the gate dielectric is first formed by CVD, sputtering or thermal growth processes followed by deposition of an overlying gate electrode material and a hardmask layer. Conventional Lithographic patterning and dry etching are then carried out to form the gate structure. A first ion implant is carried out to form doped regions (not shown) in the semiconductor substrate e.g., SDE regions adjacent both sides of the gate structures followed by a thermal activation process. One or more spacer dielectric layers are then formed e.g., LPCVD or PECVD deposition followed by a wet and/or dry etchback to form the offset spacers e.g., 20. A second higher dose ion implant is then carried out to form more highly doped S/D regions on either side of the gate structures using the offset spacers as an implant mask. First and second conductive contact regions, e.g., e.g., 14 and 19 are then formed using the preferred materials outlined above.

Referring to FIG. 1B, according to an important aspect of the invention, a first insulating dielectric (ILD) layer e.g., 22A is blanket deposited by conventional methods, e.g., LPCVD, PECVD over the process surface, followed by a conventional planarization process such as CMP. Preferably, the first ILD layer 22A is formed of one or a combinations of PETEOS, BPTEOS, BTEOS, PTEOS, TEOS, PEOX, SiC, nitrogen doped silicon oxide, silicon nitride (e.g., Si₃N₄), silicon oxynitride (e.g., SION), low-K (K<2.9) or high-K (K>5) dielectrics, and fluorine doped silicon oxide (e.g., FSG). In one embodiment, the first ILD layer 22A is deposited in a two step process to form a first lower contact etch stop layer portion 22AA including one or combinations of, SiC, nitrogen doped silicon oxide, silicon nitride (e.g., Si₃N₄), and silicon oxynitride (e.g., SION) followed by deposition of and an upper portion including one or combinations of PETEOS, BPTEOS, BTEOS, PTEOS, TEOS, PEOX, low-K (K<2.9) or high-K (K>5) dielectrics, and fluorine doped silicon oxide (e.g., FSG).

In a critical aspect of the present invention, the preferred thickness of the first dielectric layer will depend on the maximum thickness of the bottom portion of a contact opening subsequently desired to be formed and a maximum aspect ratio of the contact opening desired to enable improved contact opening etching and metal coverage in a contact metal filling process to improve device performance and reliability as explained further below.

Preferably, the aspect ratio, defined herein as the contact opening depth/contact opening width at the bottom portion of the contact opening, is preferably less than about 3.3 with the contact opening width at the bottom portion of the contact hole being less than about 70 nm. Thus the thickness of the first ILD layer following planarization including optional deposition of one or more of a hardmask layers and overlying inorganic or organic anti-reflectance (ARC) coatings, is preferably less than about 2350 Angstroms to form with the preferred contact opening aspect ratio. More preferably, the aspect ratio for the contact hole formed in the first ILD layer is less than about 4.5 with a contact opening width (bottom portion) less than about 50 nm.

In an exemplary embodiment, a hardmask layer 24A such as SiC, Si₃N₄, SiOₓN_{y} (e.g. SiON) is first formed, e.g., blanket deposited over ILD layer 22A by a conventional CVD method.

Referring to FIG. 1C, following formation of an inorganic or organic ARC layer 24B one or more resist layers e.g., 26 is deposited and patterned. The resist layer 26 may be a single or multiple layer resist including organic and inorganic materials, for example a lower organic rest layer and an overlying resist including silicon incorporated by a silylation process or including silicon monomers. The resist layer e.g., 26 may have a total thickness of about 0.1 microns to about 1.0 microns, and is preferably sensitive to wavelengths less than about 400 nm. A lithographic patterning process is carried out including radiation exposure and development by appropriate wet or dry development processes, followed by conventional dry etching processes to etch through the first ILD layer 22A to form a first set of contact openings e.g., 28A, 28B, 28C, 28D, and 28E. The contact openings may be formed in the shape of an oval (circular), butt contact, rectangular (e.g., square), or combinations thereof. For example, the contact openings may include a local interconnect opening, e.g., 28C, having the preferred aspect ratio at a lowermost (bottom) portion of the contact opening.

Referring to FIG. 1D, following removal of the resist layers, the contact openings are filled with a metal by conventional processes, including barrier layer formation, where the filling metal preferably includes Cu, W, Al, AlCu, TiN, TiW, Ti, TaN, Ta, or combination thereof. Following metal filling, a planarization process, such as metal etchback or CMP is carried out to planarize the metal filled openings to form metal filled contact interconnects e.g., 30A, 30B, 30C, 30D, and 30E.

Referring to FIG. 1E, according to an important and critical aspect of the invention, at least a second insulating dielectric (ILD) layer e.g., 22B is formed over the first ILD layer 22A such that the first and second (or more) dielectric insulating layers is sufficient to meet a required design thickness to meet a required capacitance. For example, the second ILD layer is formed by blanket depositing by conventional methods, e.g., LPCVD, PECVD one or more dielectric layers over the first ILD layer 22A followed by a conventional planarization process such as CMP. Preferably, the second ILD layer 22B is preferably formed in the same manner and using the same preferred materials as the first ILD layer 22A. In one embodiment, the second dielectric layer 22B is deposited in a two step process to form a first lower portion, e.g., a contact etch stop layer, 22BB including one or a combination of SiC, nitrogen doped silicon oxide, silicon nitride (e.g., Si₃N₄), and silicon oxynitride (e.g., SiON) and an upper portion 22B including one or a combination of PETEOS, BPTEOS, BTEOS, PTEOS, TEOS, PEOX, low-K (K<2.9) or high-K (K>5) dielectrics, and fluorine doped silicon oxide (e.g., FSG). In the exemplary embodiment preferably one or more of a hardmask layer 24C and an ARC layer 24D are formed over the ILD layer 22B according to the same preferred embodiments outlines for hardmask layer 24A and ARC layer 24B.

Referring to FIG. 1F, a similar process as outlined for forming the first set of contact interconnects 30A, 30B, 30C, 30D, and 30E is then carried out to form a second set of contact interconnects e.g., 32A, 32B, and 32C extending through the thickness of the second ILD layer 22B to make contact (e.g., including overlying and at least partially encompassing) portions of the first set of contact interconnects. The second set of contact interconnects is formed according to the same preferred embodiments and aspect ratios as the first set of contact interconnects the first ILD layer 22A. The second set of contact interconnects may have the same or different preferred aspect ratio as the second set of contact interconnects, for example having a smaller aspect ratio to ensure adequate interconnect overlap. In addition, longer (horizontal to the substrate) contact interconnects e.g., 32A may be formed to conductively connect one or more of the first set of contact openings e.g., 30A and 30B. Preferably, the length of the longer contact interconnects, e.g., 32A is between about 0.15 microns and about 500 microns.

Although not shown, conventional overlying metallization layers are then formed to make electrical contact with the second set of contact interconnects. It will be appreciated that multiple overlying dielectric layers and metallization interconnects may be subsequently formed to form multiple metallization levels overlying the first and second ILD layers.

Advantageously, according to the present invention, by forming contact interconnects in a multi-step process, for example, including at least two ILD layers with contact interconnects formed therein, electrical contact from the first overlying metallization layer to active device regions is improved. By sequentially forming contact openings followed by metal filling processes, in multiple ILD layers, the critical design requirements of forming contact openings having a bottom portion with a width of less than about 70 nm, more preferably less than about 50 nm, are able to be reliably formed in contrast with prior art processes. Included among the advantages of the present invention, is the creation of larger etch process window, leading to formation of accurately aligned, cleanly etched, and adequate metal coverage of small width contacts thereby forming more reliable contacts with improved performance to the active regions. The multi-step process allows the formation of larger aspect ratio openings in contrast with prior art processes. Other added benefits include improved ILD gap filling due to thinner contact etch stop layers and improve lithographic resolution due to thinner photoresist layers. In short, the reliability and accuracy of forming contact interconnects is improved allowing processes to be scaled down to include devices with critical dimensions (CD) of less than about 45 nm (e.g. gate length).

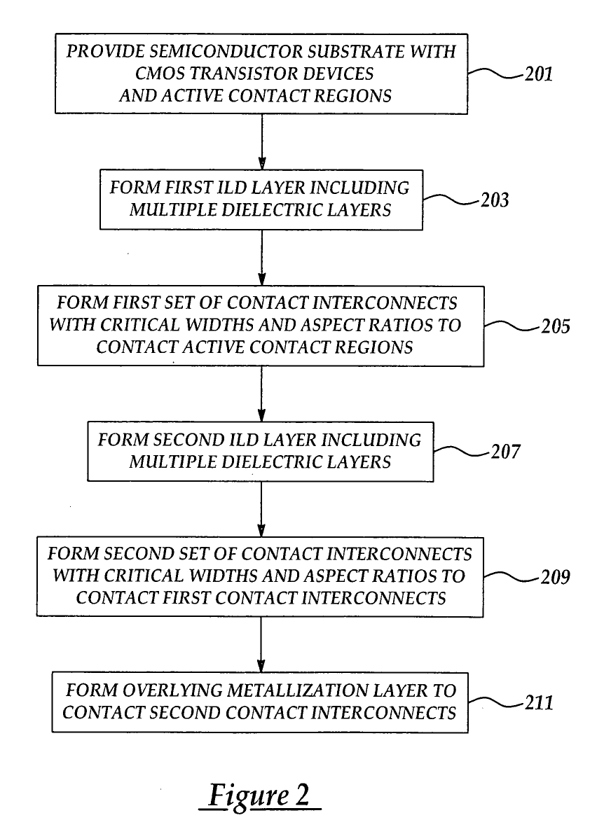

Referring to FIG. 2 is a process flow diagram including several embodiments of the present invention. In process 201, a semiconductor substrate including CMOS transistor devices is provided including active contact regions according to preferred embodiments. In process 203 a first ILD layer (including multiple dielectric layers) is formed to a first planarized thickness. In process 205, a first set of contact interconnects with critical widths and aspect ratios are formed in the first ILD layer to contact one or more of the active contact regions. In process 207, a second ILD layer (including multiple layers) is formed to a second planarized thickness. In process 209, a second set of contact interconnects with critical widths and aspect ratios are formed in the second ILD layer to contact one or more of the first contact interconnects. In process 211, an overlying metallization level including a metallization interconnects is formed to contact on or more of the second contact interconnects.

The preferred embodiments, aspects, and features of the invention having been described, it will be apparent to those skilled in the art that numerous variations, modifications, and substitutions may be made without departing from the spirit of the invention as disclosed and further claimed below.

1. A method for forming shallow contact interconnects to achieve improved patterning, etching and metal filling characteristics comprising the steps of:
providing a semiconductor substrate comprising CMOS devices including active contact regions;
forming a first set of dielectric layers to form a first thickness for etching a first set of openings through a thickness thereof comprising a bottom portion having a maximum width of less than about 70 nanometers;
etching the first set of openings to contact active contact regions;
filling the first set of openings with a first metal;
forming a second set of dielectric layers to form a second thickness for etching a second set of openings through the second thickness comprising a bottom portion having a maximum width of less than about 70 nanometers;
etching the second set of openings to provide electrical communication with the first set of openings; and,
filling the second set of openings with a second metal to form contact interconnects.

2. The method of claim 1, further comprising the step forming a metallization layer over the contact interconnects in electrical communication with at least a portion of the contact interconnects.

3. The method of claim 1, wherein the first and second set of openings have an aspect ratio with respect to the bottom portion of less than about 3.3.

4. The method of claim 1, wherein the first and second set of openings have an aspect ratio with respect to the bottom portion of less than about 4.5.

5. The method of claim 4, wherein the bottom portion has a width of less than about 50 nm.

6. The method of claim 1, wherein the first and second set of dielectric layers comprises PETEOS, BPTEOS, BTEOS, PTEOS, TEOS, PEOX, nitrogen doped silicon oxide, fluorine doped silicon oxide, SiC, silicon nitride, silicon oxynitride, or combination thereof.

7. The method of claim 1, wherein the first and second set of dielectric layers comprise lowermost portions selected from the group consisting of silicon carbide, nitrogen doped silicon oxide, silicon nitride, and silicon oxynitride.

8. The method of claim 7, wherein the first and second set of dielectric layers comprise overlying portions selected from the group consisting of PETEOS, BPTEOS, BTEOS, PTEOS, TEOS, PEOX, nitrogen doped silicon oxide, and fluorine doped silicon oxide.

9. The method of claim 1, wherein the first and second metals are selected from the group consisting of Cu, W, Al, AlCu, TiN, TiW, Ti, TaN, and Ta.

10. The method of claim 1, wherein the active contact regions are selected from the group consisting of source and drain regions and gate electrodes.

11. The method of claim 10, wherein the active contact regions comprise a conductive material selected from the group consisting of Ti, Co, Ni, Pt, W, TiSi₂, CoSi₂, NiSi, PtSi, WSi₂, TiN, and TaN.

12. The method of claim 1, wherein the first and second set of dielectric layers comprises an uppermost portion selected from the group consisting of a hardmask layer and a BARC layer.

13. The method of claim 1, wherein the steps of etching a first and second set of openings comprise forming and patterning one or more resist layers selected from the group consisting of organic resists and inorganic containing resists.

14. The method of claim 13, wherein the one or more resist layers have a thickness of between about 0.15 microns and about 1.0 microns.

15. The method of claim 1, wherein the first and second sets of openings comprise a shape selected from the group consisting of circular and rectangular.

16. The method of claim 1, wherein the first and second set of openings are selected from the group consisting of butt contact openings, openings having a length horizontal to the semiconductor substrate major surface between about 0.15 microns to about 500 microns.

17. The method of claim 1, wherein the contact interconnects are selected from the group consisting of vias, contact holes, butt contact interconnects, local interconnects, and interconnect lines.

18. A contact interconnect structure comprising:
a semiconductor substrate comprising CMOS devices including active contact regions;
a first set of dielectric layers comprising a first contact layer overlying the active contact regions comprising a first plurality of metal filled openings extending through the first contact layer thickness to provide electrical communication to the active contact regions;
a second set of dielectric layers comprising a second contact layer overlying the first contact layer comprising a second plurality of metal filled openings extending through the first contact layer thickness to provide electrical communication to the first contact region;
wherein, each of the first and second plurality of metal filled openings comprise a bottom portion having a maximum width of less than about 70 nanometers and an aspect ratio of less than about 4.5.

19. The contact interconnect structure of claim 18, wherein the bottom portion has a maximum width of less than about 50 nanometers and an aspect ratio of less than about 4.5.

20. The contact interconnect structure of claim 18, further comprising an overlying metallization layer in electrical communication with the second contact layer.

21. The contact interconnect structure of claim 18, wherein the first and second set of dielectric layers comprises PETEOS, BPTEOS, BTEOS, PTEOS, TEOS, PEOX, nitrogen doped silicon oxide, fluorine doped silicon oxide, SiC, silicon nitride, silicon oxynitride, or combination thereof.

22. The contact interconnect structure of claim 18, wherein the first and second set of dielectric layers comprise lowermost portions selected from the group consisting of silicon carbide, nitrogen doped silicon oxide, silicon nitride, and silicon oxynitride.

23. The contact interconnect structure of claim 18, wherein the first and second set of dielectric layers comprise overlying portions selected from the group consisting of PETEOS, BPTEOS, BTEOS, PTEOS, TEOS, PEOX, nitrogen doped silicon oxide, and fluorine doped silicon oxide.

24. The contact interconnect structure of claim 18, wherein the first and second first and second plurality of metal filled openings comprise conductive materials selected from the group consisting of Cu, W, Al, AlCu, TiN, TiW, Ti, TaN, and Ta.

25. The contact interconnect structure of claim 18, wherein the active contact regions are selected from the group consisting of source and drain regions and gate electrodes.

26. The contact interconnect structure of claim 18, wherein the gate electrode comprises a gate structure having a gate length of less than about 45 nm.

27. The contact interconnect structure of claim 18, wherein the active contact regions comprise a conductive material selected from the group consisting of Ti, Co, Ni, Pt, W, TiSi₂, CoSi₂, NiSi, PtSi, WSi₂, TiN, and TaN.

28. The contact interconnect structure of claim 18, wherein the first and second set of dielectric layers comprises an uppermost portion selected from the group consisting of a hardmask layer and a BARC layer.

29. The contact interconnect structure of claim 18, wherein the first and second plurality of metal filled openings comprise a shape selected from the group consisting of circular and rectangular.

30. The contact interconnect structure of claim 18, wherein the first and second first and second first and second plurality of metal filled openings are selected from the group consisting of vias, contact holes, butt contact interconnects, local interconnects, and interconnect lines.

31. The contact interconnect structure of claim 30, wherein the interconnect lines have a length horizontal to the semiconductor substrate major surface between about 0.15 microns to about 500 microns.

32. A contact interconnect structure comprising:
at least a first contact layer comprising a first plurality of metal filled openings extending through the first contact layer thickness to provide electrical communication to overlying and underlying conductive regions;
wherein, the first plurality of metal filled openings comprise a bottom portion having a maximum width of less than about 70 nanometers and an aspect ratio of less than about 3.3.

33. The contact interconnect structure of claim 32, wherein the bottom portion has a maximum width of less than about 50 nanometers and an aspect ratio of less than about 4.5.

34. The contact interconnect structure of claim 32, wherein the at least a first contact layer comprises one of an overlying an underlying second contact layer.

35. The contact interconnect structure of claim 32, wherein the underlying conductive regions comprise active conductive regions selected from the group consisting of source and drain regions and gate electrodes.

36. The contact interconnect structure of claim 35, wherein the gate electrode comprises a gate structure having a gate length of less than about 45 nm.

37. The contact interconnect structure of claim 32, wherein the overlying conductive regions comprise a metallization layer.
